(19) United States
(12) Patent Application Publication
(10) Pub. No.: US 2024/0301213 A1
(43) Pub. Date: Sep. 12, 2024

(54) GAS BARRIER FILM AND METHOD FOR MANUFACTURING SAME

(71) Applicant: LINTEC Corporation, Tokyo (JP)

(72) Inventors: Nana SHINDO, Saitama-shi (JP); Satoshi NAGANAWA, Tokyo (JP)

(73) Assignee: LINTEC Corporation, Tokyo (JP)

(21) Appl. No.: 18/592,596

(22) Filed: Mar. 1, 2024

(30) Foreign Application Priority Data
Mar. 2, 2023 (JP) 2023-031961

(51) Int. Cl. C09D 1/00; C23C 14/48

(52) U.S. Cl. CPC C09D 1/00; C23C 14/48

(57) ABSTRACT

The present invention relates to a method for manufacturing a gas barrier film, including at least steps 1 to 3 (each step is as defined in the specification) in this order;
a gas barrier film including: a substrate; and a polysilazane-based compound-derived layer on at least one surface side of the substrate, wherein the polysilazane-based compound-derived layer satisfies a specific requirement; and
a gas barrier film including: a substrate; and a gas barrier layer laminate provided on at least one surface side of the substrate and including a gas barrier layer (XG) not adjacent to the substrate and a gas barrier layer (YG) located closer to the substrate than the layer (XG) and adjacent to the layer (XG), the gas barrier layers (XG) and (YG) being directly laminated, wherein the gas barrier layer laminate satisfies a specific requirement.

### CROSS-REFERENCE TO RELATED APPLICATION

This application is based upon and claims the benefit of priority from the prior Japanese Patent Application No. 2023-031961, filed on Mar. 2, 2023; the entire contents of which are incorporated herein by reference.

### TECHNICAL FIELD

The present invention relates to a gas barrier film, and a method for manufacturing the same.

### BACKGROUND ART

In recent years, a gas barrier film has been widely used as a substrate material and a sealing material. The gas barrier film is required to have a high gas barrier property that can suppress permeation of water vapor, oxygen and the like.

For example, Patent Literature 1 discloses a gas barrier laminate including a substrate and a gas barrier unit, wherein the gas barrier unit includes at least two inorganic layers, at least one of the at least two inorganic layers is a silicon oxynitride layer, and the silicon oxynitride layer has a graded composition region in which an abundance of oxygen decreases and an abundance of nitrogen increases toward a substrate side in a thickness direction within a layer having a thickness of 25 nm or more, and a ratio of the thickness of the graded composition region to a total thickness of the silicon oxynitride layer is 0.15 or more.

### CITATION LIST

### Patent Literature

Patent Literature 1: WO 2014/157685

### SUMMARY OF INVENTION

### Technical Problem

Meanwhile, in recent years, gas barrier films are required to have not only excellent gas barrier properties but also, for example, a characteristic of being capable of suppressing a decrease in gas barrier properties (also referred to as “bending durability” in the present specification) even when repeatedly subjected to bending. A gas barrier film having excellent bending durability is preferable because, for example, even in a case where the gas barrier film is repeatedly subjected to bending in the course of storage and transportation of the gas barrier film, during manufacture and use of a product using the gas barrier film, or the like, characteristics required based on the gas barrier properties of the gas barrier film before bending are easily satisfied.

In addition, for example, when the gas barrier film is developed for flexible uses, the bending durability is also required.

Patent Literature 1 describes that the cited gas barrier laminate also has extremely high water vapor barrier properties and is excellent in folding resistance (a water vapor transmission rate is not increased so much even after a folding test).

As described above, a gas barrier laminate having excellent gas barrier properties and excellent folding resistance has been proposed.

However, as a result of investigation by the present inventors, it has been found that there is room for further investigation for a gas barrier film having excellent gas barrier properties and excellent bending durability.

The present invention has been made in view of the above circumstances, and an object thereof is to provide a gas barrier film having excellent gas barrier properties and excellent bending durability, and a method for manufacturing the same.

### Solution to Problem

The present inventors have found that the above problems can be solved by a method for manufacturing a gas barrier film including at least the following steps 1 to 3, and have completed the present invention. In addition, the present inventors have found that the above problems can also be solved by a gas barrier film that satisfies a specific configuration and requirements which will be described below, and have completed the present invention.

That is, the present invention provides the following [1] to [11].

[1] A method for manufacturing a gas barrier film, the method including at least the following steps 1 to 3 in this order:
step 1: forming an unmodified polysilazane-based compound layer (Y);
step 2: forming an unmodified polysilazane-based compound layer (X) on an exposed surface of the layer (Y) to directly laminate the layer (Y) and the layer (X); and
step 3: forming a gas barrier layer laminate in which a gas barrier layer (XG) and a gas barrier layer (YG) are directly laminated by performing a modification treatment from a surface of the layer (X) on a side opposite to the layer (Y) to simultaneously perform the modification treatment on at least a part of the layer (X) and the layer (Y).

[2] The method for manufacturing a gas barrier film according to [1], wherein the step 1 is the following step 11:
step 11: forming the unmodified polysilazane-based compound layer (Y) on at least one surface side of a substrate.

[3] The method for manufacturing a gas barrier film according to [1] or [2], wherein, in the step 3, the modification treatment is performed on the entire layer (X) as well as on at least a part of the layer (Y) in a thickness direction of the layer (Y) from an interface between the layer (X) and the layer (Y) toward a surface of the layer (Y) opposite to the layer (X).

[4] The method for manufacturing a gas barrier film according to any one of [1] to [3], wherein a ratio [(Yt)/(Xt)] of a thickness (Yt) of the layer (Y) to a thickness (Xt) of the layer (X) is 1 or more.

[5] The method for manufacturing a gas barrier film according to any one of [1] to [4], wherein the gas barrier layer laminate has a thickness of from 25 to 10000 nm.

[6] A gas barrier film including: a substrate; and a polysilazane-based compound-derived layer on at least one surface side of the substrate,
wherein the polysilazane-based compound-derived layer, when analyzed in a thickness direction from a surface thereof opposite to the substrate using X-ray photoelectron spectroscopy (XPS), shows a graph having a peak having at least one shoulder at a location different from a peak top, where a horizontal axis is a thickness of the polysilazane-based compound-derived layer, a value of a nitrogen element ratio (atom %), which is a content of nitrogen relative to a total content of silicon, oxygen, and nitrogen elements, obtained by analysis results of the XPS, is plotted on a vertical axis, and the graph is drawn based on plotted points.

[7] The gas barrier film according to [6], wherein the shoulder is an inflection point.

[8] The gas barrier film according to [6] or [7], wherein the shoulder is present within a range of ±50 nm from a position of the peak top.

[9] The gas barrier film according to any one of [6] to [8], wherein the shoulder is present on a rising side of the peak top.

[10] The gas barrier film according to any one of [6] to [9], wherein, in the polysilazane-based compound-derived layer, a region in which the nitrogen element ratio is 5 atom % or more has a thickness of from 5 to 10000 nm.

[11] A gas barrier film including: a substrate; and a gas barrier layer laminate provided on at least one surface side of the substrate and including a gas barrier layer (XG) not adjacent to the substrate and a gas barrier layer (YG) located closer to the substrate than the layer (XG) and adjacent to the layer (XG), the gas barrier layers (XG) and (YG) being directly laminated,
wherein the gas barrier layer laminate, when analyzed in a thickness direction from a surface thereof opposite to the substrate using X-ray photoelectron spectroscopy (XPS), shows a graph having a peak having at least one shoulder at a location different from a peak top, where a horizontal axis is a thickness of the gas barrier layer laminate, a value of a nitrogen element ratio (atom %), which is a content of nitrogen relative to a total content of silicon, oxygen, and nitrogen elements, obtained by analysis results of the XPS, is plotted on a vertical axis, and the graph is drawn based on plotted points.

### Advantageous Effects of Invention

The present invention can provide a gas barrier film having excellent gas barrier properties and excellent bending durability, and a method for manufacturing the same.

### BRIEF DESCRIPTION OF DRAWINGS

FIG. 1 is a schematic cross-sectional view showing an example of a laminate formed through steps 1 and 2 in a method for manufacturing a gas barrier film according to an embodiment of the present invention.

FIG. 2 is a schematic cross-sectional view showing an example of a gas barrier film manufactured through step 3 in the method for manufacturing a gas barrier film according to an embodiment of the present invention.

FIG. 3 is a schematic cross-sectional view showing an example of a gas barrier film corresponding to an embodiment of a comparative example.

FIG. 4 is a graph drawn from measurement results obtained by XPS analysis of a gas barrier layer laminate included in a gas barrier film of Example 1.

FIG. 5 is a graph drawn from measurement results obtained by XPS analysis of a gas barrier layer laminate included in a gas barrier film of Example 2.

### DESCRIPTION OF EMBODIMENTS

Hereinafter, the present invention will be described in detail using embodiments.

In the present specification, the lower and upper limits of a preferable numerical range (for example, a range of content) described in series can each be independently combined. For example, from the description “preferably from 10 to 90, more preferably from 30 to 60”, the “preferred lower limit (10)” and the “preferred upper limit (60)” can be combined as “from 10 to 60”. In the present specification, unless otherwise specified, for example, when a numerical range is simply described as “from 10 to 90”, the numerical range represents a range of 10 or more and 90 or less.

Similarly, from the descriptions “preferably 10 or more, more preferably 30 or more” and “preferably 90 or less, more preferably 60 or less” for the same matter, the “preferred lower limit (10)” and the “more preferred upper limit (60)” can be combined to as “10 or more and 60 or less”.

In the present specification, the term “gas barrier property” refers to a property of suppressing permeation of water vapor or oxygen, and the term “gas barrier film” refers to a film having a gas barrier property.

In addition, as described above, the term “bending durability” means a property of being capable of suppressing a decrease in a gas barrier property even when the gas barrier film is repeatedly subjected to bending.

In the present specification, the term “(meth)acrylic” is used as a term meaning either one or both of “acrylic” and “methacrylic”.

### Method for Manufacturing Gas Barrier Film

A method for manufacturing a gas barrier film according to an embodiment of the present invention includes at least the following steps 1 to 3 in this order:
step 1: forming an unmodified polysilazane-based compound layer (Y);
step 2: forming an unmodified polysilazane-based compound layer (X) on an exposed surface of the layer (Y) to directly laminate the layer (Y) and the layer (X); and
step 3: forming a gas barrier layer laminate in which a gas barrier layer (XG) and a gas barrier layer (YG) are directly laminated by performing a modification treatment from a surface of the layer (X) on a side opposite to the layer (Y) to simultaneously perform the modification treatment on at least a part of the layer (X) and the layer (Y).

The gas barrier film obtained by the manufacture method has excellent gas barrier properties and excellent bending durability.

Hereinafter, the respective steps for the gas barrier film will be described in order.

### Step 1

The step 1 is a step of forming an unmodified polysilazane-based compound layer (Y) (also referred to as “layer (Y)” in the present specification).

In an embodiment of the step 1, the layer (Y) can be formed, for example, on at least one surface side of the substrate or on at least one surface side of a release liner, and is preferably formed on one or both surface sides of the substrate. That is, the step 1 is preferably the following step 11:
step 11: forming the unmodified polysilazane-based compound layer (Y) on at least one surface side of the substrate.

Examples of the method for forming the layer (Y) on at least one surface side of the substrate or at least one surface side of the release liner in the step 1 include a method in which a liquid prepared by dissolving or dispersing, in a solvent, at least one polysilazane-based compound and an additional component that may be used as necessary is directly applied to at least one surface of the substrate or at least one surface of the release liner by a known coating method, and the resulting coating film is dried to form the layer.

Another example is a method in which a liquid obtained by dissolving or dispersing, in a solvent, at least one polysilazane-based compound and an additional component that may be used as necessary is applied onto an additional layer such as an anchor coat formed on the substrate or release liner by a known coating method, and the obtained coating film is dried to form the layer.

Here, the substrate, the release liner, the polysilazane-based compound layer (Y), the polysilazane-based compound, and the additional component that may be used as necessary in the step 1 will be described.

### Substrate

As the substrate, a plastic film is preferably used.

Examples of resins contained in the plastic film include polyimide, polyamide, polyamide-imide, polyphenylene ether, polyether ketone, polyether ether ketone, polyolefin, copolymers of olefin and another monomer, polyester, polycarbonate, polysulfone, polyethersulfone, polyphenylene sulfide, acrylic resin, cycloolefin-based polymer, and aromatic polymer.

Among these, from the perspective of excellent transparency, a plastic film containing one or more resins selected from the group consisting of polyester, polyamide, polycarbonate, and a cycloolefin-based polymer is more preferable, a plastic film containing one or more resins selected from polyester and a cycloolefin-based polymer is even more preferable, and a plastic film containing polyester as a main component is still more preferable. Here, the phrase “containing as a main component” refers to a resin contained in the largest amount among the resins constituting the plastic film, and the amount of the resin is, for example, preferably from 50 to 100 mass %, more preferably from 80 to 100 mass %, and even more preferably from 90 to 100 mass %, in 100 mass % of a total amount of the resins constituting the plastic film.

Examples of the polyester include polyethylene terephthalate, polybutylene terephthalate, polyethylene naphthalate, polyarylate, and polylactic acid. The polyester is preferably one or more selected from polyethylene terephthalate and polyethylene naphthalate, and more preferably polyethylene terephthalate.

Examples of the polyamide include wholly aromatic polyamides, nylon 6, nylon 66, and nylon copolymers.

Examples of the polycarbonate include polymers obtained by reacting a bisphenol such as 2,2-bis(4-hydroxyphenyl)propane (also known as bisphenol A), 2,2-bis(4-hydroxyphenyl)butane, 1,1-bis(4-hydroxyphenyl)cyclohexane, 1,1-bis(4-hydroxyphenyl)isobutane, and 1,1-bis(4-hydroxyphenyl)ethane with phosgene or diphenyl carbonate.

Examples of the cycloolefin-based polymer include a norbornene-based polymer, a monocyclic olefin-based polymer, a cyclic conjugated diene-based polymer, a vinyl alicyclic hydrocarbon polymer, and hydrides thereof. Specific examples thereof include “APEL (trade name)” (ethylene-cycloolefin copolymer available from Mitsui Chemicals, Inc.), “ARTON (trade name)” (norbornene-based polymer available from JSR Corporation), and “ZEONOR (trade name)” (norbornene-based polymer available from Zeon Corporation).

In addition, the substrate may be a plastic film having only one or two or more of the above-described resins. For example, it may be a single-layer film composed of one plastic film, or a multilayer film in which a plurality of plastic films are laminated.

The plastic film may contain various additives as long as the effects of the present invention are not impaired. Examples of the various additives include an ultraviolet absorber, an antistatic agent, a stabilizer, an antioxidant, a plasticizer, a lubricant, a colorant, and a pigment. A content of these additives can be appropriately determined according to the purpose.

The substrate may be subjected to a primer treatment, and examples of the primer treatment include providing a primer layer on one or both surfaces of the substrate, performing a corona treatment, and performing a flame treatment. The “primer treatment” refers to a treatment for improving the adhesiveness between the substrate and another layer. Similarly, the “primer layer” refers to a layer provided between the substrate and another layer for the purpose of improving the adhesiveness between the substrate and the other layer.

A thickness of the substrate is not particularly limited as long as the effects of the present invention are exhibited, and the thickness is preferably from 0.01 to 500 μm, preferably from 0.1 to 400 μm, more preferably from 1 to 300 μm, even more preferably from 5 to 200 μm, still more preferably from 10 to 140 μm, and even still more preferably from 20 to 90 μm.

Here, the “thickness of the substrate” means the thickness of the entire substrate; for example, in the case of using the above-described multilayer film in which two or more layers are laminated, the thickness of the substrate means a total thickness of all the layers constituting the substrate.

### Release Liner

The release liner preferably has a shape of a sheet or a film. The shape of a sheet or a film is not limited to an elongated shape and also includes the shape of a short flat plate.

Examples of the release liner include: a paper substrate such as glassine paper, coat paper, and wood-free paper; a laminated paper in which a thermoplastic resin such as polyethylene or polypropylene is laminated on such a paper substrate; the above-mentioned paper substrate sealed with, for example, cellulose, starch, polyvinyl alcohol, or acrylic-styrene resin; or, a plastic film, such as a polyester film such as polyethylene terephthalate, polybutylene terephthalate, or polyethylene naphthalate, and a polyolefin film such as polyethylene or polypropylene; and glass.

Furthermore, the release liner may have a release agent layer provided on a paper substrate or a plastic film from the view point of ease in handling. In a case where a release agent layer is provided, the release agent layer can be formed, for example, using a known release agent, such as a silicone-based release agent, a fluorine-based release agent, an alkyd-based release agent, or an olefin-based release agent.

The release liner also has a role of protecting the polysilazane-based compound layer (Y) when the layer (Y) is stored or transported in a state before being used in the manufacture of the gas barrier film. Then, the release liner is released from the layer (Y) in a predetermined step after its role is finished. In addition, the release liner can be used as it is, for example, as a release liner in a gas barrier film manufactured using the polysilazane-based compound layer. In this case, as described above, the release liner also has a role of protecting the gas barrier film when the manufactured gas barrier film is stored or transported. Then, the release liner is released from the gas barrier film in a predetermined step after its role is finished.

### Unmodified Polysilazane-Based Compound Layer (Y)

The “unmodified polysilazane-based compound layer (Y)” is a layer containing at least a polysilazane-based compound and a hydrolysate thereof, and is a layer before a modification treatment. The gas barrier layer (YG) can be formed by modifying at least a part of the unmodified polysilazane-based compound layer (Y) by the modification treatment in the step 3 which will be described later. In other words, the polysilazane-based compound layer (Y) may also be regarded as a precursor layer of the gas barrier layer (YG) including a polysilazane-based compound and a hydrolysate thereof. On the other hand, the “gas barrier layer (YG)” may also be referred to as a gas barrier layer formed by modifying at least a part of the polysilazane-based compound layer (Y). However, in the present specification, the term “gas barrier layer” means not only the modified region but also the entire “polysilazane-based compound layer including the modified region”.

The “hydrolysate of the polysilazane-based compound” means a product resulting from a hydrolysis reaction of the polysilazane-based compound, and includes, for example, not only a compound having a silanol group produced by hydrolysis of the polysilazane-based compound, but also a condensate produced by a condensation reaction between the compounds.

### Polysilazane-Based Compound

The polysilazane-based compound is a compound having a repeating unit containing a —Si—N-bond (silazane bond) in the molecule. Specifically, a compound having a repeating unit represented by the following general formula (1) is preferable.

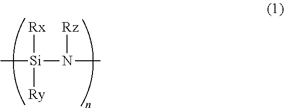

In the general formula (1), n represents a repeating unit and represents an integer of 1 or more. Rx, Ry, and Rz each independently represent a non-hydrolyzable group such as a hydrogen atom, an unsubstituted or substituted alkyl group, an unsubstituted or substituted cycloalkyl group, an unsubstituted or substituted alkenyl group, an unsubstituted or substituted aryl group, or an alkylsilyl group.

In the present invention, the polysilazane-based compounds described in, for example, JP 63-16325 B, JP 62-195024 A, JP 63-81122 A, JP 1-138108 A, JP 2-84437 A, JP 2-175726 A, JP 4-63833 A, JP 5-238827 A, JP 5-345826 A, JP 2005-36089 A, JP 6-122852 A, JP 6-299118 A, JP 6-306329 A, JP 9-31333 A, JP 10-245436 A, JP 2003-514822 T, and WO 2011/107018 can also be used.

As the polysilazane-based compound, perhydropolysilazane in which Rx, Ry, and Rz are all hydrogen atoms in the general formula (1) is preferred from the perspective of easy availability and possible formation of a gas barrier layer having excellent gas barrier properties.

Further, as the polysilazane-based compound, a commercially available product sold as a glass coating material or the like can be used as it is.

For the polysilazane-based compound, one type may be used alone, or two or more types may be used in combination.

In addition, a number average molecular weight (Mn) of the polysilazane-based compound is not particularly limited, and a compound having a number average molecular weight of from 100 to 50000 can be suitably used.

A weight average molecular weight (Mw) of the polysilazane-based compound is preferably from 200 to 100000, more preferably from 500 to 50000, and even more preferably from 1000 to 30000.

The number average molecular weight (Mn) and the weight average molecular weight (Mw) can be determined as values calibrated with standard polystyrene by gel permeation chromatography.

From the perspective of easily forming a gas barrier layer having more excellent gas barrier properties, a content of the polysilazane-based compound and a hydrolysate thereof in the layer (Y) is preferably 50 mass % or more, more preferably 70 mass % or more, even more preferably 80 mass % or more, and 100 mass % or less, in 100 mass % of the polysilazane-based compound layer (Y).

### Additional Component

The layer (Y) may contain an additional component in addition to the polysilazane-based compound and hydrolysate thereof described above as long as the object of the present invention is not hindered. Examples of the additional component include an oxidation catalyst, a curing agent, another polymer, an anti-aging agent, a light stabilizer, and a flame retardant. For these components, one type may be used alone, or two or more types may be used in combination.

In addition, when the layer (Y) contains an additional component, it preferably contains an oxidation catalyst.

Examples of the oxidation catalyst include metal catalysts such as palladium-based catalysts and platinum-based catalysts; amine-based catalysts such as N,N,N′,N′-tetramethyl-1,6-diaminohexane and N,N-diethylethanolamine; and hydrogen-abstracting catalysts such as phenone-based catalysts such as benzophenone and acetophenone. Among these catalysts, a metal catalyst is preferable.

When the layer (Y) contains the oxidation catalyst, a content of the oxidation catalyst in the layer (Y) is not particularly limited as long as the effects of the present invention are exhibited. From the perspective of more easily exhibiting the effects of the present invention, for example, the content of the oxidation catalyst in the polysilazane-based compound layer (Y) is preferably from 0.001 to 10 mass %, more preferably from 0.01 to 5 mass %, and even more preferably from 0.05 to 1 mass % in 100 mass % of the polysilazane-based compound layer (Y).

A thickness of the layer (Y) is not particularly limited as long as the effects of the present invention are exhibited, and is preferably from 10 to 8000 nm, more preferably from 15 to 4000 nm, even more preferably from 20 to 1000 nm, still more preferably from 30 to 800 nm, and even still more preferably from 40 to 400 nm.

### Solvent

Examples of the solvent include organic solvents such as aromatic hydrocarbon-based solvents such as benzene, toluene and xylene; ester-based solvents such as ethyl acetate and butyl acetate; ketone-based solvents such as acetone, methyl ethyl ketone and methyl isobutyl ketone; aliphatic hydrocarbon-based solvents such as n-pentane, n-hexane and n-heptane; and alicyclic hydrocarbon-based solvents such as cyclopentane and cyclohexane. For these organic solvents, one type may be used alone, or two or more types may be used in combination.

The coating method for the liquid in which the polysilazane-based compound is dissolved or dispersed in a solvent is not particularly limited, and examples thereof include a bar coating method, a spin coating method, a dipping method, a roll coating method, a gravure coating method, a knife coating method, an air knife coating method, a roll knife coating method, a die coating method, a screen printing method, a spray coating method, and a gravure offset method.

A known drying method such as hot air drying, hot roll drying, or infrared irradiation can be used as a method for drying the coating film for forming the polysilazane-based compound layer (Y).

A drying temperature during drying is not particularly limited as long as the effects of the present invention are exhibited, and is preferably from 60 to 150° C., more preferably from 80 to 110° C., and even more preferably from 90 to 105° C.

A drying time during drying is not particularly limited as long as the effects of the present invention are exhibited, and is, for example, from several tens of seconds to several tens of minutes, preferably 30 seconds or more and 10 minutes or less, more preferably 45 seconds or more and 5 minutes or less, even more preferably 1 minute or more and 3 minutes or less, and still more preferably 1 minute 30 seconds or more and 2 minutes 30 seconds or less.

### Step 2

The step 2 is a step of forming an unmodified polysilazane-based compound layer (X) (in the present specification, also referred to as a “layer (X)”) on an exposed surface of the layer (Y) to directly laminate the layer (Y) and the layer (X).

In the step 2, the layer (X) is preferably formed as an outermost surface layer.

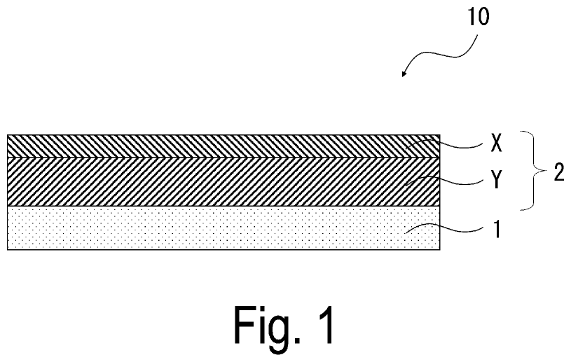

Here, in the present specification, the phrase “directly laminating” refers to, for example, as shown in FIG. 1, a configuration in which the layer (Y) and the layer (X) are in direct contact with each other in the absence of another layer between the layers.

Examples of a method for forming the layer (X) on the exposed surface of the layer (Y) to directly laminate the layer (Y) and the layer (X) in the step 2 include a method of directly applying a liquid obtained by dissolving or dispersing in a solvent at least one polysilazane-based compound and an additional component that may be used as necessary to the exposed surface of the layer (Y) by a known coating method and drying the obtained coating film to form the layer.

A method for forming the layer (X) on the exposed surface of the layer (Y) in the step 2 may be the same as the method described as the method for forming the layer (Y) on at least one surface side of the substrate or at least one surface side of the release liner in the step 1, and suitable embodiments thereof are also the same. That is, the solvent, the coating method, and the drying method are also the same as those described above in the section “Step 1”, and suitable embodiments thereof are also the same.

### Unmodified Polysilazane-Based Compound Layer (X)

The “unmodified polysilazane-based compound layer (X)” is a layer containing at least a polysilazane-based compound and a hydrolysate thereof, and is a layer before a modification treatment. The gas barrier layer (XG) can be formed by modifying at least a part of the unmodified polysilazane-based compound layer (X) by the modification treatment in the step 3 which will be described later. In other words, the polysilazane-based compound layer (X) may also be regarded as a precursor layer of the gas barrier layer (XG) including a polysilazane-based compound and a hydrolysate thereof. On the other hand, the “gas barrier layer (XG)” may also be referred to as a gas barrier layer formed by modifying at least a part of the entire polysilazane-based compound layer (X). As described above, in the present specification, the term “gas barrier layer” means not only the modified region but also the entire “polysilazane-based compound layer including the modified region”.

Here, in the step 2, the polysilazane-based compound and hydrolysate thereof are the same as the polysilazane-based compound and hydrolysate thereof described in the section “the step 1”, respectively, and suitable embodiments thereof are also the same.

From the perspective of easily forming a gas barrier layer having more excellent gas barrier properties, a content of the polysilazane-based compound and a hydrolysate thereof in the layer (X) is preferably 50 mass % or more, more preferably 70 mass % or more, even more preferably 80 mass % or more, and 100 mass % or less, in 100 mass % of the polysilazane-based compound layer (X).

### Additional Component

The layer (X) may contain an additional component in addition to the polysilazane-based compound and hydrolysate thereof described above as long as the object of the present invention is not hindered. Examples of the additional component include an oxidation catalyst, a curing agent, another polymer, an anti-aging agent, a light stabilizer, and a flame retardant. For these components, one type may be used alone, or two or more types may be used in combination.

In addition, when the layer (X) contains an additional component, it preferably contains an oxidation catalyst. Examples of the oxidation catalyst which may be contained in the layer (X) are the same as the oxidation catalysts that may be contained in the layer (Y) described above, and suitable embodiments thereof are also the same. When the layer (X) contains the oxidation catalyst, a content of the oxidation catalyst in the layer (X) is not particularly limited as long as the long as the effects of the present invention are exhibited, and examples thereof include the same suitable range as that for the content of the oxidation catalyst in the layer (Y) in the case where the layer (Y) contains the oxidation catalyst.

A thickness of the layer (X) is not particularly limited as long as the effects of the present invention are exhibited, and is preferably from 1 to 2000 nm, more preferably from 1 to 1000 nm, even more preferably from 1 to 500 nm, still more preferably from 2 to 200 nm, even still more preferably from 2 to 100 nm, even still more preferably from 3 to 80 nm, even still more preferably from 4 to 40 nm, and even still more preferably from 5 to 30 nm.

A ratio [(Yt)/(Xt)] of the thickness (Yt) of the layer (Y) to the thickness (Xt) of the layer (X) is not particularly limited as long as the effects of the present invention are exhibited, and is preferably from 1 to 100, more preferably from 3 to 60, even more preferably from 5 to 30, and still more preferably from 10 to 20.

### Step 3

The step 3 is a step of forming a gas barrier layer laminate in which a gas barrier layer (XG) and a gas barrier layer (YG) are directly laminated by performing a modification treatment from a surface of the layer (X) on a side opposite to the layer (Y) to simultaneously perform the modification treatment on at least a part of the layer (X) and the layer (Y).

As used herein, the phrase “simultaneously perform the modification treatment” means that the layer (X) and the layer (Y) are first subjected to the modification treatment at the stage of the step 3. Therefore, it is not necessary that the layer (X) and the layer (Y) are modified at exactly the same time. For example, the same modification treatment may be performed in order from the layer (X) side, in the thickness direction of the laminate, from the surface of the layer (X) opposite to the layer (Y) to the surface of the layer (Y) opposite to the layer (X).

In the step 3, the surface of the layer (X) on the side opposite to the layer (Y) is preferably an exposed surface.

Further, in the step 3, it is preferable that the entire layer (X) is subjected to the modification treatment. Namely, in the step 3, preferably, the modification treatment is simultaneously performed on the entire layer (X) as well as on at least a part of the layer (Y) in a thickness direction of the layer (Y) from an interface between the layer (X) and the layer (Y) toward the surface of the layer (Y) opposite to the layer (X).

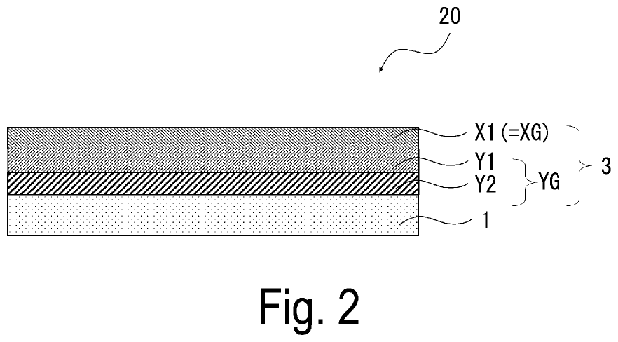

A schematic cross-sectional view of a gas barrier film according to a suitable embodiment of the present invention is shown in FIG. 2. The gas barrier film shown in FIG. 2 is a schematic cross-sectional view showing a suitable example of a gas barrier film 20 obtained by performing the modification treatment of the step 3 on a laminate 10 before the modification treatment, which includes a laminate 2 in which the polysilazane-based compound layer (X) and the polysilazane-based compound layer (Y) are directly laminated as shown in FIG. 1. The gas barrier film 20 shown in FIG. 2 includes a gas barrier layer laminate 3 in which a gas barrier layer (XG) obtained by modifying the entire layer (X) and a gas barrier layer (YG) obtained by modifying the layer (Y), by the modification treatment of the step 3, are directly laminated, the gas barrier layer (XG) is formed of a modified region (X1), and the gas barrier layer (YG) includes: a modified region (Y1) adjacent to the gas barrier layer (XG); and an unmodified region (Y2) located closer to the substrate 1 than the modified region (Y1).

By directly laminating the layer (Y) and the layer (X) in the step 2 and then subjecting the layer (Y) and the layer (X) to the modification treatment simultaneously in the step 3, it is possible to suppress a decrease in interfacial adhesion at an interface due to a difference in shrinkage stress between the layer (Y) and the layer (X) during the modification treatment. Therefore, it is considered that it is possible to prevent a decrease in gas barrier properties and a decrease in bending resistance caused by a decrease in interfacial adhesion at the interface, and to form a gas barrier layer laminate having more excellent gas barrier properties and excellent bending durability.

Further, in the gas barrier layer laminate obtained through the steps 2 and 3, the gas barrier layer (YG) and the layer (XG) are directly laminated, and, therefore, even if a very small number of pin holes are present in the layer (XG) and the layer (YG), there is a extremely low probability that positions of the pin holes on the layer (XG) side coincide with positions of the pin holes present on the layer (YG) side.

Therefore, for example, it is presumed that, even when water vapor or the like enters from the layer (XG) side through the pin holes of the layer (XG), the water vapor or the like is blocked at an interface between the layer (XG) and the layer (YG).

Therefore, it is considered that a gas barrier layer laminate having more excellent gas barrier properties and excellent bending durability can be formed through the steps 2 and 3.

### Modification Treatment

Examples of the modification treatment used in the step 3 include ion implantation and vacuum ultraviolet light irradiation (irradiation with excimer laser or the like). Among these, ion implantation is preferable from the perspective of being able to provide higher gas barrier performance. In the ion implantation, an amount of ions to be implanted into the polysilazane-based compound layer (X) and the layer (Y) may be appropriately determined according to the intended use of the gas barrier film to be formed that includes a gas barrier layer (necessary gas barrier property, transparency, and the like).

These modification treatments are preferably performed from the exposed surface side of the polysilazane-based compound layer (X).

Examples of the ions to be implanted include: ions of noble gases such as argon, helium, neon, krypton, and xenon; ions of fluorocarbon, hydrogen, nitrogen, oxygen, carbon dioxide, chlorine, fluorine, and sulfur; ions of alkane gases such as methane, ethane, propane, butane, pentane, and hexane; ions of alkene gases such as ethylene, propylene, butene, and pentene; ions of alkadiene gases such as pentadiene and butadiene; ions of alkyne gases such as acetylene and methyl acetylene; ions of aromatic hydrocarbon gases such as benzene, toluene, xylene, indene, naphthalene, and phenanthrene; ions of cycloalkane gases such as cyclopropane and cyclohexane; ions of cycloalkene gases such as cyclopentene and cyclohexene; ions of conductive metals such as gold, silver, copper, platinum, nickel, palladium, chromium, titanium, molybdenum, niobium, tantalum, tungsten, and aluminum; and ions of silane (SiH₄).

For the ions described above, one type may be used alone, or two or more types may be used in combination. Of those ions, at least one type of ions selected from the group consisting of hydrogen, nitrogen, oxygen, argon, helium, neon, xenon, and krypton is preferable, at least one type of ions selected from the group consisting of argon and helium is more preferable, and helium ions are even more preferable, from the perspectives of easier implantation and that a gas barrier layer having superior gas barrier property can be obtained.

The method of ion implantation is not limited, and examples include a method of irradiating ions (ion beam) accelerated by an electric field and a method of implanting plasma ions. Of these, the latter, a method of implanting plasma ions, is preferable because a gas barrier layer can be easily produced.

The plasma ion implantation method is preferably: (I) a method of implanting ions present in the plasma generated using an external electric field into the polysilazane-based compound layers (X) and (Y); or (II) a method of implanting ions present in the plasma generated only by the electric field generated by a negative high voltage pulse applied to the layer into the polysilazane-based compound layers (X) and (Y) without using an external electric field.

In the method (I) above, the pressure during ion implantation (pressure during plasma ion implantation) is preferably from 0.01 to 1 Pa. When the pressure during plasma ion implantation is within this range, ions can be easily, efficiently, and uniformly implanted, and the target gas barrier layer can be efficiently formed.

The method (II) does not require increasing the degree of decompression, deploys simple processing operation, and reduces the processing time greatly. Also, the entire layer can be treated uniformly, and ions in the plasma can be continuously implanted into the polysilazane-based compound layer with high energy when a negative high voltage pulse is applied. Furthermore, good quality ions can be implanted uniformly into the polysilazane-based compound layer by simply applying a negative high voltage pulse to the layer without requiring any other special means such as a high-frequency power source such as radio frequency (abbreviated as “RF” hereafter) or microwave.

In either of the above methods (I) and (II), the pulse width when applying a negative high voltage pulse, that is, during ion implantation, is preferably from 1 to 15 usec. When the pulse width is within this range, ions can be implanted more easily, efficiently, and uniformly.

Furthermore, the applied voltage when generating plasma is preferably from −1 to −50 kV, more preferably from −1 to −30 kV, and particularly preferably from −5 to −20 kV. When ion implantation is performed at an applied voltage of less than-1 kV, a sufficient ion implantation amount (dose) is likely to be obtained, and the desired performance is likely to be obtained. Meanwhile, when ion implantation is performed at an applied voltage of greater than-50 kV, the film builds up static charge during ion implantation, and the occurrence of problems such as coloration of the film can be suppressed, which is preferable.

Examples of the ion species used in plasma ion implantation include the same as those exemplified as the ions to be implanted, and suitable embodiments thereof are also the same.

A time for ion implantation is preferably 350 seconds or more, more preferably 400 seconds or more, even more preferably 500 seconds or more, still more preferably 600 seconds or more, and even still more preferably 700 seconds or more, from the perspective of sufficiently securing the thickness of the modified region. An upper limit is not particularly limited, and is preferably 10000 seconds or less, more preferably 5000 seconds or less, even more preferably 3000 seconds or less, still more preferably 2000 seconds or less, and even still more preferably 1000 seconds or less, from the perspective of shortening a tact time during manufacture.

A plasma ion implantation device is used when ions in plasma are implanted into the polysilazane-based compound layer (X) and the layer (Y).

Specific examples of the plasma ion implantation device include (i) a plasma ion implantation device that generates plasma using an external electric field, such as a high-frequency power source of microwave, applies a high voltage pulse, and induces and implants ions in the plasma, and (ii) a plasma ion implantation device that implants ions in a plasma generated only by an electric field generated by application of a high voltage pulse without using an external electric field.

A method that deploys the plasma ion implantation device of (i) and (ii) is described in WO 2010/021326.

In the plasma ion implantation device of (i) and (ii), a high voltage pulse power supply is also used as a plasma generating means for generating plasma. Therefore, other special means such as a high-frequency power source such as RF and microwave are not necessary. A plasma is generated by simply applying a negative high voltage pulse, and ions in the plasma are continuously implanted into the polysilazane-based compound layer (X) and the layer (Y). Thus, a gas barrier film formed with a gas barrier layer laminate in which the gas barrier layer (XG) and the layer (YG) are directly laminated can be mass-produced.

The thickness of the portion where ions are implanted can be controlled by implantation conditions, such as the species of ions, the applied voltage, and the processing time, and can be determined according to, for example, the thicknesses of the polysilazane-based compound layer (X) and the layer (Y) and the intended use of the gas barrier film, and is, for example, from 5 to 10000 nm.

A fact that ions have been implanted can be confirmed by performing elemental analysis measurement on a surface of the gas barrier layer laminate using X-ray photoelectron spectroscopy (XPS).

### Gas Barrier Layer (XG)

As described above, the gas barrier layer (XG) (also referred to as “layer (XG)” in the present specification) is a layer obtained by subjecting the layer (X) formed in the step 2 to the modification treatment in the step 3.

As described above, the layer (XG) is a gas barrier layer obtained by modifying at least a part of the layer (X), and the entire layer (X) is preferably modified.

It is presumable that, in an embodiment of the present invention, in the region in which the modification treatment is performed by the ion implantation described above, the modification causes a deprotonation reaction, by which hydrogen bonds of a Si—H bond and a N—H bond of polysilazane are cut, and formation of a new Si—N bond, resulting in change of the film structure to a fine film structure. Therefore, it is conceivable that the region in which the modification treatment is performed has a higher element ratio of nitrogen and, accordingly, the element ratios of oxygen and silicon decrease.

A thickness of the layer (XG) is not particularly limited as long as the effects of the present invention are exhibited, and is preferably from 1 to 2000 nm, more preferably from 1 to 1000 nm, even more preferably from 1 to 500 nm, still more preferably from 2 to 200 nm, even still more preferably from 2 to 100 nm, even still more preferably from 3 to 80 nm, even still more preferably from 4 to 40 nm, and even still more preferably from 5 to 30 nm.

### Gas Barrier Layer (YG)

As described above, the gas barrier layer (YG) (also referred to as “layer (YG)” in the present specification) is a layer obtained by subjecting the layer (Y) formed in the step 1 to the modification treatment in the step 3.

As described above, the layer (YG) is a gas barrier layer obtained by modifying at least a part of the layer (Y).

A thickness of the layer (YG) is not particularly limited as long as the effects of the present invention are exhibited, and is preferably from 10 to 8000 nm, more preferably from 15 to 4000 nm, even more preferably from 20 to 1000 nm, still more preferably from 30 to 800 nm, and even still more preferably from 40 to 400 nm.

A thickness of the gas barrier layer laminate in which the gas barrier layer (XG) and the gas barrier layer (YG) are directly laminated and which is obtained in the step 3 is not particularly limited as long as the effects of the present invention are exhibited, and is preferably from 25 to 10000 nm, more preferably from 30 to 5000 nm, even more preferably from 35 to 3000 nm, still more preferably from 40 to 2000 nm, even still more preferably from 45 to 1000 nm, even still more preferably from 50 to 500 nm, and even still more preferably from 100 to 400 nm.

In addition, in the gas barrier layer laminate in which the gas barrier layer (XG) and the gas barrier layer (YG) are directly laminated and which is obtained in the step 3, thicknesses of regions modified by the modification treatment (hereinafter also referred to as “modified film thickness”) are not particularly limited as long as the effects of the present invention are exhibited, but are preferably from 5 to 10000 nm, more preferably from 10 to 5000 nm, even more preferably from 15 to 1000 nm, still more preferably from 20 to 500 nm, even still more preferably from 30 to 200 nm, even still more preferably from 40 to 150 nm, and even still more preferably from 50 to 100 nm.

In the present specification, the “modified film thickness” refers to a film thickness at which a nitrogen element ratio is 5 atom % or more based on element amounts obtained from elemental analysis of silicon, nitrogen, and oxygen performed in a depth direction of the gas barrier layer laminate in the obtained gas barrier film using an XPS measurement analyzer. Specifically, the “modified film thickness” can be measured by a method which will be described in the Examples later.

A ratio [(Ygt)/(Xgt)] of the thickness (Ygt) of the layer (YG) to the thickness (Xgt) of the layer (XG) is not particularly limited as long as the effects of the present invention are exhibited, and is preferably from 1 to 100, more preferably from 3 to 60, even more preferably from 5 to 30, and still more preferably from 10 to 20.

A ratio [(Ygmt)/(Xgmt)] of a modified film thickness (Ygmt) in the layer (YG) to a modified film thickness (Xgmt) in the layer (XG) is not particularly limited as long as the effects of the present invention are exhibited, and is preferably from 0.1 to 100, more preferably from 0.5 to 10, even more preferably from 1 to 7, and still more preferably from 1.5 to 3.

### Additional Step

The method for manufacturing a gas barrier film according to an embodiment of the present invention may include an additional step besides the steps 1 to 3, if necessary.

For example, the method may include, as necessary, a step of laminating a protective film or a release liner on the surface of the gas barrier layer (XG) side of the gas barrier film obtained through the steps 1 to 3.

In addition, in the case of a gas barrier film including the gas barrier layer laminate on one surface of the substrate, the method may include, as necessary, a step of laminating a protective film or a release liner on a surface of the substrate opposite to the surface having the gas barrier layer laminate.

One or more types selected from the protective film and the release liner are provided, and thus the substrate and the gas barrier layer are protected when the gas barrier film is stored or transported in a state of an intermediate product before being used in a final product. The one or more types selected from the protective film and the release liner are peeled off in a predetermined step after its/their role is finished.

The protective film is not particularly limited, and has a role of protecting the gas barrier film during, for example, storage or transportation of the gas barrier film and is peeled off in a predetermined step.

The protective film is preferably in the shape of a sheet or a film. The shape of a sheet or a film is not limited to an elongated shape and also includes the shape of a short flat plate.

Since the protective film is typically applied to a surface of a gas barrier layer laminate or a surface of the substrate, the protective film preferably has a structure in which a pressure sensitive adhesive layer is provided on a substrate, from the perspective of preventing unintended release of the protective film. In this case, the pressure sensitive adhesive layer is provided on a surface of the protective film on the gas barrier film layer side. When the protective film includes a pressure sensitive adhesive layer, the protective film is attached to the gas barrier film in a releasable manner. As the substrate of the protective film, the same material as that for the substrate or the like of the release liner can be used. Also, as the substrate of the protective film, the same thickness as that of the substrate or the like of the release liner can be used.

Examples of a pressure sensitive adhesive constituting the pressure sensitive adhesive layer of the protective film include an acrylic pressure sensitive adhesive, a urethane-based pressure sensitive adhesive, a silicone-based pressure sensitive adhesive, a rubber-based pressure sensitive adhesive, a pressure sensitive adhesive containing a polyolefin-based polymer, and a pressure sensitive adhesive containing a polyolefin-based copolymer. The pressure sensitive adhesive layer more preferably contains at least one of a polyolefin-based polymer or a polyolefin-based copolymer. Examples of the polyolefin-based polymer include polyethylene and polypropylene. Examples of the polyolefin-based copolymer include an ethylene-vinyl acetate copolymer and an ethylene-(meth)acrylic acid copolymer.

Furthermore, examples of a commercially available protective film containing a polyolefin-based pressure sensitive adhesive, which can be used as the protective film, include SUNYTECT PAC-3-50THK and SUNYTECT PAC-2-70, available from Sun A. Kaken Co., Ltd.

In an embodiment of the present invention, the gas barrier film obtained by the manufacture method may have, for example, an anchor coat, a gas barrier layer other than the gas barrier layer (XG) and the layer (YG), a smoothing layer, a refractive index adjusting layer, or the like as the additional layer between the substrate and the gas barrier layer laminate. These layers can be formed by known methods.

In an embodiment of the present invention, a substantial thickness of the gas barrier film obtained by the manufacture method is not particularly limited as long as the effects of the present invention are exhibited, and can be appropriately determined depending on the application and the like of the gas barrier film. From the perspective of handling properties, the substantial thickness of the gas barrier film is preferably from 1 to 1000 μm, more preferably from 5 to 200 μm, and even more preferably from 15 to 100 μm.

The “substantial thickness” refers to the thickness in a use state. That is, when the gas barrier film includes the release sheet or protective film described above, the thickness of the release sheet or protective film that is removed in use of the gas barrier film is not included in the “substantial thickness”.

In an embodiment of the present invention, a water vapor transmission rate of the gas barrier film obtained by the manufacture method under an atmosphere of 40° C. and 90% relative humidity is preferably 5.0×10⁻⁴ g·m⁻²·day⁻¹ or less, more preferably 4.5×10⁻⁴ g·m⁻²·day⁻¹ or less, more preferably 4.0×10⁻⁴ g·m⁻²·day⁻¹ or less, even more preferably 3.5×10⁻⁴ g·m⁻²·day⁻¹ or less, still more preferably 3.0×10⁻⁴ g·m⁻²·day⁻¹ or less, even still more preferably 2.0×10⁻⁴ g·m⁻²·day⁻¹ or less, and even still more preferably 1.5×10⁻⁴ g·m⁻²·day⁻¹ or less, from the perspective of securing high gas barrier properties. In addition, a lower limit of the water vapor transmission rate is not particularly limited, and may be, for example, 1.0×10⁻⁶ g·m⁻²·day⁻¹ or more in an embodiment of the present invention.

The water vapor transmission rate can be specifically measured by a method which will be described in the Examples below.

### First Gas Barrier Film

A first gas barrier film according to an embodiment of the present invention (hereinafter also referred to as a “first gas barrier film”) includes: a substrate; and a polysilazane-based compound-derived layer on at least one surface side of the substrate. The polysilazane-based compound-derived layer, when analyzed in a thickness direction from a surface thereof opposite to the substrate using X-ray photoelectron spectroscopy (XPS), shows a graph having a peak having at least one shoulder at a location different from a peak top, where a horizontal axis is a thickness of the polysilazane-based compound-derived layer, a value of a nitrogen element ratio (atom %), which is a content of nitrogen relative to a total content of silicon, oxygen, and nitrogen elements, obtained by analysis results of the XPS, is plotted on a vertical axis, and the graph is drawn based on plotted points.

The gas barrier film which satisfies the requirements described above has excellent gas barrier properties and excellent bending durability.

### Base Material

The “substrate” included in the first gas barrier film according to an embodiment of the present invention is the same as the “substrate” described above in the section “Method for manufacturing gas barrier film” according to an embodiment of the present invention, suitable embodiments thereof are also the same, and thus descriptions thereof are omitted here.

### Polysilazane-Based Compound-Derived Layer

The polysilazane-based compound-derived layer, when analyzed in a thickness direction from a surface thereof opposite to the substrate using X-ray photoelectron spectroscopy (XPS), shows a graph having a peak having at least one shoulder at a location different from a peak top, where a horizontal axis is a thickness of the polysilazane-based compound-derived layer, a value of a nitrogen element ratio (atom %), which is a content of nitrogen relative to a total content of silicon, oxygen, and nitrogen elements, obtained by analysis results of the XPS, is plotted on a vertical axis, and the graph is drawn based on plotted points.

In addition, the “polysilazane-based compound-derived layer” may be any layer in which a polysilazane-based compound is used as a raw material constituting the layer, may be a layer formed of a polysilazane-based compound, or may be a polysilazane-based compound layer modified by, for example, the modification treatment described above in the section “Method for manufacturing gas barrier film” according to an embodiment of the present invention.

Here, the “polysilazane-based compound” of the polysilazane-based compound-derived layer is the same as the “polysilazane-based compound” described above in the section “Method for manufacturing gas barrier film” which is an embodiment of the present invention, suitable embodiments thereof are also the same, and thus the descriptions thereof are omitted here.

The graph of the polysilazane-based compound-derived layer forms a peak having at least one shoulder at a location different from the peak top, and is specifically drawn by a method which will be described in the Examples later.

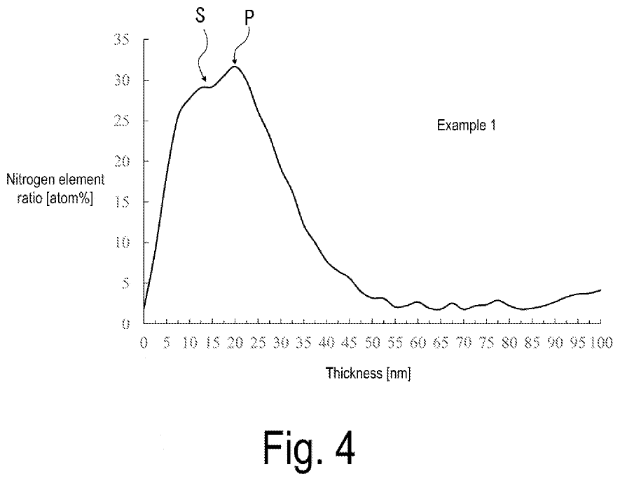

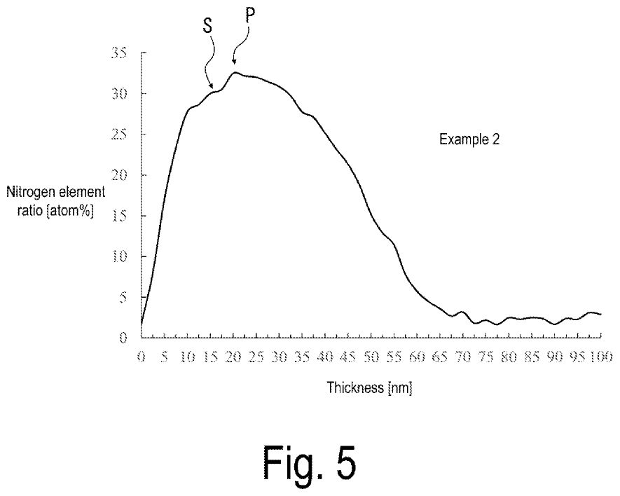

Examples of the graphs are shown in FIGS. 4 and 5. Hereinafter, the graph will be described with reference to the graph of FIG. 4.

As shown in FIG. 4, the “peak top” in the graph is a portion indicated by a symbol P in FIG. 4, and the “shoulder” in the graph is a portion indicated by a symbol S in FIG. 4.

In an embodiment of the present invention, the graph preferably has one peak top. That is, the graph preferably has one peak top and has the shoulder at at least one location selected from a rising side of the peak top and a falling side of the peak top.

Here, in the present specification, the “rising side of the peak top” refers to, for example, a region on the left side of the peak top P in FIG. 4, that is, a region on the surface layer side of the polysilazane-based compound-derived layer with respect to the position of the peak top P (the side where the value of the thickness on the horizontal axis in the graph is smaller than the value at the position of the peak top).

In the present specification, the “falling side of the peak top” refers to, for example, a region on the right side of the peak top P in FIG. 4, that is, a region on the substrate layer side of the polysilazane-based compound-derived layer with respect to the position of the peak top P (the side where the value of the thickness on the horizontal axis in the graph is greater than the value at the position of the peak top).

Here, for example, in the case of a gas barrier film as shown in Comparative Example 1 which will be described later, it is considered that the graph has two peak tops.

In an embodiment of the present invention, the shoulder is preferably an inflection point in the graph.

In an embodiment of the present invention, the shoulder is present preferably within a range of +50 nm, more preferably within a range of +30 nm, and even more preferably within a range of +15 nm from the position of the peak top.

In an embodiment of the present invention, the shoulder is preferably present on the rising side of the peak top.

In an embodiment of the present invention, in the graph, preferred embodiments relating to the shoulder can be freely combined.

For example, in an embodiment of the present invention, the shoulder is more preferably an inflection point in the graph, is present within a range of +50 nm (more preferably +30 nm, and even more preferably +15 nm) from the position of the peak top, and is present on the rising side of the peak top. In other words, in an embodiment of the present invention, the shoulder is more preferably an inflection point in the graph, and is present between a position of −50 nm (more preferably −30 nm, and even more preferably −15 nm) from the position of the peak top and the position of the peak top.

In an embodiment of the present invention, preferably, in the graph, a point where a slope of a tangent line thereof decreases at least once is present on the side of the shoulder opposite to the peak top and within the 20 nm (more preferably the 15 nm, and even more preferably the 10 nm) from the position of the shoulder, and a point where the slope of the tangent line thereof increases at least once is present on the peak top side of the shoulder and between the shoulder and the peak top.

In addition, in the polysilazane-based compound-derived layer, a thickness of the region in which the nitrogen element ratio is 5 atom % or more is preferably 5 to 10000 nm, more preferably 10 to 5000 nm, even more preferably 15 to 1000 nm, still more preferably 20 to 500 nm, even still more preferably 30 to 200 nm, even still more preferably 40 to 150 nm, and even still more preferably 50 to 100 nm.

Specifically, the “thickness of the region in which the nitrogen element ratio is 5 atom % or more” can be measured by a method which will be described in the Examples later.

### Additional Layer

In an embodiment of the present invention, the first gas barrier film may include, for example, a gas barrier layer, an anchor coat, a smoothing layer, a refractive index adjusting layer, and the like besides the polysilazane-based compound-derived layer between the substrate and the polysilazane-based compound-derived layer. These layers can be formed by known methods. In addition, for example, a protective film or a release liner may be provided on a surface of the polysilazane-based compound-derived layer of the first gas barrier film as necessary. In addition, for example, in the case of a gas barrier film including the polysilazane-based compound-derived layer on one surface of the substrate, a protective film or a release liner may be provided on the surface of the substrate opposite to the surface having the polysilazane-based compound-derived layer, if necessary.

The protective film and the release liner are the same as the “protective film” and the “release liner” described above in the section “Method for manufacturing gas barrier film” according to an embodiment of the present invention, respectively, suitable embodiments thereof are also the same, and thus descriptions thereof are omitted here.

In an embodiment of the present invention, a substantial thickness of the first gas barrier film is not particularly limited as long as the effects of the present invention are exhibited, and can be appropriately determined depending on the application and the like of the gas barrier film. From the perspective of handling properties, the substantial thickness of the first gas barrier film is preferably from 1 to 1000 μm, more preferably from 5 to 200 μm, and even more preferably from 15 to 100 μm.

The “substantial thickness” refers to the thickness in a use state. That is, when the first gas barrier film includes the release sheet or protective film described above, the thickness of the release sheet or protective film that is removed in use of the first gas barrier film is not included in the “substantial thickness”.

In an embodiment of the present invention, a water vapor transmission rate of the first gas barrier film under an atmosphere of 40° C. and 90% relative humidity is preferably 5.0×10⁻⁴ g·m⁻²·day⁻¹ or less, more preferably 4.5×10⁻⁴ g·m⁻²·day⁻¹ or less, more preferably 4.0×10⁻⁴ g·m⁻²·day⁻¹ or less, even more preferably 3.5×10⁻⁴ g·m⁻²·day⁻¹ or less, still more preferably 3.0×10⁻⁴ g·m⁻²·day⁻¹ or less, even still more preferably 2.0×10⁻⁴ g·m⁻²·day⁻¹ or less, and even still more preferably 1.5×10⁻⁴ g·m⁻²·day⁻¹ or less, from the perspective of securing high gas barrier properties. In addition, a lower limit of the water vapor transmission rate is not particularly limited, and may be, for example, 1.0×10⁻⁶ g·m⁻²·day⁻¹ or more in an embodiment of the present invention.

The water vapor transmission rate can be specifically measured by a method which will be described in the Examples below.

### Second Gas Barrier Film

A second gas barrier film according to an embodiment of the present invention (hereinafter also referred to as “a second gas barrier film”) includes: a substrate; and a gas barrier layer laminate provided on at least one surface side of the substrate and including a gas barrier layer (XG) not adjacent to the substrate and a gas barrier layer (YG) located closer to the substrate than the layer (XG) and adjacent to the layer (XG), the gas barrier layers (XG) and (YG) being directly laminated. The gas barrier layer laminate, when analyzed in a thickness direction from a surface thereof opposite to the substrate using X-ray photoelectron spectroscopy (XPS), shows a graph having a peak having at least one shoulder at a location different from a peak top, where a horizontal axis is a thickness of the gas barrier layer laminate, a value of a nitrogen element ratio (atom %), which is a content of nitrogen relative to a total content of silicon, oxygen, and nitrogen elements, obtained by analysis results of the XPS, is plotted on a vertical axis, and the graph is drawn based on plotted points.

### Substrate

The “substrate” included in the second gas barrier film according to an embodiment of the present invention is the same as the “substrate” described above in the section “Method for manufacturing gas barrier film” according to an embodiment of the present invention, suitable embodiments thereof are also the same, and thus descriptions thereof are omitted here.

### Gas Barrier Layer Laminate

In the gas barrier layer laminate of the second gas barrier film according to an embodiment of the present invention, a gas barrier layer (XG) which is not adjacent to the substrate and a gas barrier layer (YG) which is located closer to the substrate than the layer (XG) and is adjacent to the layer (XG) are directly laminated.

The gas barrier layer laminate, when analyzed in a thickness direction from a surface opposite to the substrate using X-ray photoelectron spectroscopy (XPS) shows a graph having a peak having at least one shoulder at a location different from a peak top, where a horizontal axis is a thickness of the gas barrier layer laminate, a value of a nitrogen element ratio (atom %), which is a content of nitrogen relative to a total content of silicon, oxygen, and nitrogen elements, obtained by analysis results of the XPS is plotted on a vertical axis, and the graph is drawn based on plotted points.

The graph of the gas barrier layer laminate forms a peak having at least one shoulder at a location different from the peak top, and is specifically drawn by a method which will be described in the Examples later. The graph is the same as the “graph” described above in the section “First gas barrier film”, and suitable embodiments thereof are also the same.

Thus, in an embodiment of the present invention, the graph preferably has one peak top. That is, the graph preferably has one peak top and has the shoulder at at least one location selected from a rising side of the peak top and a falling side of the peak top.

In an embodiment of the present invention, the shoulder is preferably an inflection point in the graph.

In an embodiment of the present invention, the shoulder is present preferably within a range of ±50 nm, more preferably within a range of ±30 nm, and even more preferably within a range of ±15 nm from the position of the peak top.

In an embodiment of the present invention, the shoulder is preferably present on the rising side of the peak top.

In an embodiment of the present invention, in the graph, preferred embodiments relating to the shoulder can be freely combined.

For example, in an embodiment of the present invention, the shoulder is more preferably an inflection point in the graph, is present within a range of ±50 nm (more preferably ±30 nm, and even more preferably +15 nm) from the position of the peak top, and is present on the rising side of the peak top. In other words, in an embodiment of the present invention, the shoulder is more preferably an inflection point in the graph, and is present between a position of −50 nm (more preferably −30 nm, and even more preferably −15 nm) from the position of the peak top and the position of the peak top.

In an embodiment of the present invention, preferably, in the graph, a point where a slope of a tangent line thereof decreases at least once is present on the side of the shoulder opposite to the peak top and within the 20 nm (more preferably the 15 nm, and even more preferably the 10 nm) from the position of the shoulder, and a point where the slope of the tangent line thereof increases at least once is present on the peak top side of the shoulder and between the shoulder and the peak top.

The “gas barrier layer (XG)” included in the second gas barrier film according to an embodiment of the present invention is preferably the same as the “gas barrier layer (XG)” described above in the section “Method for manufacturing gas barrier film” according to an embodiment of the present invention.

Further, in the second gas barrier film, the gas barrier layer (XG) is preferably located on an outermost surface.

The “gas barrier layer (YG)” included in the second gas barrier film according to an embodiment of the present invention is preferably the same as the “gas barrier layer (YG)” described above in the section “Method for manufacturing gas barrier film” according to an embodiment of the present invention.

In addition, in the gas barrier layer laminate included in the second gas barrier film, a thickness of the region in which the nitrogen element ratio is 5 atom % or more is preferably 5 to 10000 nm, more preferably 10 to 5000 nm, even more preferably 15 to 1000 nm, still more preferably 20 to 500 nm, even still more preferably 30 to 200 nm, even still more preferably 40 to 150 nm, and even still more preferably 50 to 100 nm.

Specifically, the “thickness of the region in which the nitrogen element ratio is 5 atom % or more” can be measured by a method which will be described in the Examples later.

A ratio [(Ygt)/(Xgt)] of the thickness (Ygt) of the layer (YG) to the thickness (Xgt) of the layer (XG) in the gas barrier layer laminate included in the second gas barrier film is not particularly limited as long as the effects of the present invention are exhibited, and is preferably from 1 to 100, more preferably from 3 to 60, even more preferably from 5 to 30, and still more preferably from 10 to 20.

A ratio [(Ygmt)/(Xgmt)] of a modified film thickness (Ygmt) in the layer (YG) to a modified film thickness (Xgmt) in the layer (XG) is not particularly limited as long as the effects of the present invention are exhibited, and is preferably from 0.1 to 100, more preferably from 0.5 to 10, even more preferably from 1 to 7, and still more preferably from 1.5 to 3.

### Additional Layer

In an embodiment of the present invention, the second gas barrier film may have, for example, an anchor coat, a gas barrier layer other than the gas barrier layer (XG) and the layer (YG), a smoothing layer, a refractive index adjusting layer, or the like as the additional layer between the substrate and the gas barrier layer laminate. These layers can be formed by known methods.

In an embodiment of the present invention, a substantial thickness of the second gas barrier film is not particularly limited as long as the effects of the present invention are exhibited, and can be appropriately determined depending on the application and the like of the gas barrier film. From the perspective of handling properties, the substantial thickness of the second gas barrier film is preferably from 1 to 1000 μm, more preferably from 5 to 200 μm, and even more preferably from 15 to 100 μm.

The “substantial thickness” refers to the thickness in a use state. That is, when the second gas barrier film includes the release sheet or protective film described above, the thickness of the release sheet or protective film that is removed in use of the second gas barrier film is not included in the “substantial thickness”.

In an embodiment of the present invention, a water vapor transmission rate of the second gas barrier film under an atmosphere of 40° C. and 90% relative humidity is preferably 5.0×10⁻⁴ g·m⁻²·day⁻¹ or less, more preferably 4.5×10⁻⁴ g·m⁻²·day⁻¹ or less, more preferably 4.0×10⁻⁴ g·m⁻²·day⁻¹ or less, even more preferably 3.5×10⁻⁴ g·m⁻²·day⁻¹ or less, still more preferably 3.0×10⁻⁴ g·m⁻²·day⁻¹ or less, even still more preferably 2.0×10⁻⁴ g·m⁻²·day⁻¹ or less, and even still more preferably 1.5×10⁻⁴ g·m⁻²·day⁻¹ or less, from the perspective of securing high gas barrier properties. In addition, a lower limit of the water vapor transmission rate is not particularly limited, and may be, for example, 1.0×10⁻⁶ g·m⁻²·day⁻¹ or more in an embodiment of the present invention.

The water vapor transmission rate can be specifically measured by a method which will be described in the Examples below.

In an embodiment of the present invention, exemplified is a gas barrier film including: a substrate; and a polysilazane-based compound-derived layer on at least one surface side of the substrate, wherein the polysilazane-based compound-derived layer, when analyzed in a thickness direction from a surface opposite to the substrate using X-ray photoelectron spectroscopy (XPS), shows a graph a peak having at least one shoulder at a location different from a peak top, where a horizontal axis is a sputtering time, a value of a nitrogen element ratio (atom %), which is a content of nitrogen relative to a total content of silicon, oxygen, and nitrogen elements, obtained by analysis results of the XPS is plotted on a vertical axis, and the graph is drawn based on plotted points.

Here, the substrate and the polysilazane-based compound-derived layer are the same as those described in the above section “First gas barrier film”, and thus descriptions thereof are omitted.

The analysis by XPS can be performed using, for example, an XPS measurement analyzer which will be described in the Examples below. In this case, for the gas barrier film, the sputtering time can be a value obtained by converting the thickness of 2.5 nm into a sputtering time of 0.1 minutes for the values of the respective “thicknesses” in the above section “First Gas Barrier Film”, and a suitable range thereof is also the same.

Further, in an embodiment of the present invention, exemplified is a gas barrier film including: a substrate; and a gas barrier layer laminate provided on at least one surface side of the substrate and including a gas barrier layer (XG) not adjacent to the substrate and a gas barrier layer (YG) located closer to the substrate than the layer (XG) and adjacent to the layer (XG), the gas barrier layers (XG) and (YG) being directly laminated, wherein the gas barrier layer laminate, when analyzed in a thickness direction from a surface opposite to the substrate using X-ray photoelectron spectroscopy (XPS), shows a graph having a peak having at least one shoulder at a location different from a peak top, where a horizontal axis is a sputtering time, a value of a nitrogen element ratio (atom %), which is a content of nitrogen relative to a total content of silicon, oxygen, and nitrogen elements, obtained by analysis results of the XPS is plotted on a vertical axis, and the graph is drawn based on plotted points.

Here, the substrate and the gas barrier layer laminate are the same as those described in the above section “Second gas barrier film”, and thus descriptions thereof are omitted.

The analysis by XPS can be performed using, for example, an XPS measurement analyzer which will be described in the Examples below. In this case, for the gas barrier film, the sputtering time can be a value obtained by converting the thickness of 2.5 nm into a sputtering time of 0.1 minutes for the values of the respective “thicknesses” in the above section “Second Gas Barrier Film”, and a suitable range thereof is also the same.

### EXAMPLES

The present invention will be specifically described with reference to examples below, but the present invention is not limited to the following examples. Physical property values in the Examples are values measured by the following methods.

### Thicknesses of Substrate and Polysilazane Layer

The thickness of the substrate used in each of the Examples and each of the Comparative Examples was measured using a constant pressure thickness meter (Model number: “PG-02J”, standard specifications: in accordance with JIS K6783:1994, JIS Z1702:1994, and JIS Z1709:1995) available from TECLOCK Co., Ltd.

The thickness (film thickness) of the polysilazane layer formed in each of the Examples and each of the Comparative Examples was measured using a spectroscopic ellipsometer (product name “alpha-SE”, available from J. A. Woollam).

### Manufacture of Gas Barrier Film

A gas barrier film was manufactured by the following method.

### Example 1

On an untreated surface (PET face) of a polyethylene terephthalate (PET) film (“A-4160”, available from TOYOBO Co., Ltd.) that had undergone a primer treatment on one face and that had a thickness of 50 μm, perhydropolysilazane (available from DNF; weight average molecular weight: 10000 g/mol) was applied and heated and dried at 100° C. for 2 minutes, and thus a polysilazane layer as a first polysilazane-based compound layer (Y) was formed. The film thickness of the first polysilazane layer was 250 nm.

Next, perhydropolysilazane (available from DNF, weight average molecular weight: 10000 g/mol) was applied onto an exposed surface of the first polysilazane layer, and heated and dried at 100° C. for 2 minutes, and thus a polysilazane layer as a second polysilazane-based compound layer (X) was formed. The film thickness of the second polysilazane layer was 20 nm.

Next, plasma ion implantation was performed on a laminate composed of the polysilazane-based compound layers (X) and (Y) from an exposed surface side of the second polysilazane layer using a plasma ion implantation device under the following conditions to simultaneously perform a modification treatment on at least a part of the second polysilazane layer and the first polysilazane layer. Thus, a gas barrier layer laminate in which a gas barrier layer (XG) and a gas barrier layer (YG) were directly laminated was formed, and a gas barrier film including the gas barrier layer laminate was obtained.

The plasma ion implantation device and plasma ion implantation conditions used in the modification treatment are as follows.

### Plasma Ion Implantation Device

RF power source: model number “RF” 56000, available from JEOL Ltd.
High voltage pulse power supply: “PV-3-HSHV-0835” available from Kurita Manufacturing Co., Ltd.

### Plasma Ion Implantation Condition

Plasma generating gas: helium (He)
Gas flow rate: 100 sccm
Duty ratio: 0.5%
Repetition frequency: 1000 Hz
Applied voltage: −8 kV
RF power source: frequency 13.56 MHz, applied electric power 1000 W
Chamber internal pressure: 0.2 Pa
Pulse width: 5 usec
Treatment time (ion implantation time): 600 seconds

### Example 2

A gas barrier film was obtained in the same manner as in Example 1, except that the treatment time for the modification treatment using the plasma ion implantation device was changed to 800 seconds.

### Comparative Example 1

On an untreated surface (PET face) of a polyethylene terephthalate (PET) film (“A-4160”, available from TOYOBO Co., Ltd.) that had undergone a primer treatment on one face and that had a thickness of 50 μm, perhydropolysilazane (available from DNF; weight average molecular weight: 10000 g/mol) was applied and heated and dried at 100° C. for 2 minutes, and thus a first polysilazane layer was formed. The film thickness of the first polysilazane layer was 200 nm.

Next, plasma ion implantation was performed from the exposed surface side of the first polysilazane layer under the following conditions using a plasma ion implantation device, and the surface of the first polysilazane layer was modified to form a first gas barrier layer.

Next, perhydropolysilazane (available from DNF, weight average molecular weight: 10000 g/mol) was applied onto an exposed surface of the first gas barrier layer, and heated and dried at 100° C. for 2 minutes, and thus a second polysilazane layer was formed. The film thickness of the second polysilazane layer was 250 nm.

Next, plasma ion implantation was performed from the exposed surface side of the second polysilazane layer under the following conditions using a plasma ion implantation device, and the surface of the second polysilazane layer was modified, and thus a second gas barrier layer was formed.

By the above operations, a gas barrier layer laminate in which the two gas barrier layers were directly laminated was formed, and a gas barrier film including the gas barrier layer laminate was obtained.

The plasma ion implantation device and plasma ion implantation conditions used in the modification treatment of the first and second polysilazane layers of Comparative Example 1 are as follows.

Plasma Ion Implantation Device
RF power source: model number “RF” 56000, available from JEOL Ltd.
High voltage pulse power supply: “PV-3-HSHV-0835” available from Kurita Manufacturing Co., Ltd.

### Plasma Ion Implantation Condition

Plasma generation gas: argon (Ar)
Gas flow rate: 100 sccm
Duty ratio: 0.5%
Repetition frequency: 1000 Hz
Applied voltage: −8 kV
RF power source: frequency 13.56 MHz, applied electric power 1000 W
Chamber internal pressure: 0.2 Pa
Pulse width: 5 usec
Treatment time (ion implantation time): 200 seconds

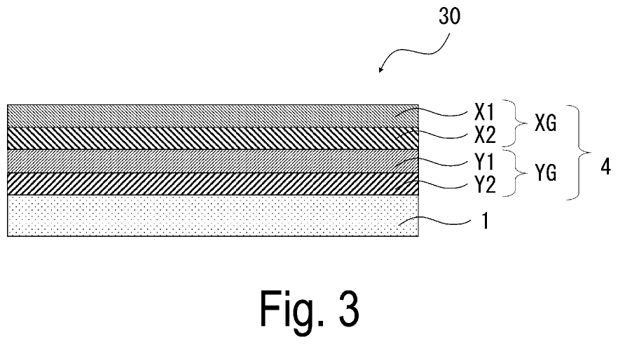

Here, FIG. 3 shows a schematic cross-sectional view of a gas barrier film including a gas barrier layer laminate in which the gas barrier layer (XG) and the gas barrier layer (YG) formed by sequential modification treatment are directly laminated as in Comparative Example 1.

In the case of the gas barrier film obtained by the sequential modification treatment illustrated in Comparative Example 1, as shown in FIG. 3, the gas barrier film includes a gas barrier layer laminate 4 in which a gas barrier layer (XG) and a gas barrier layer (YG) are directly laminated, the gas barrier layer (XG) includes a modified region (X1) located on the surface side opposite to the substrate 1 and an unmodified region (X2) located closer to the substrate 1 than the modified region (X1), and the gas barrier layer (YG) includes a modified region (Y1) adjacent to the gas barrier layer (XG) and an unmodified region (Y2) located closer to the substrate 1 than the modified region (Y1).

### Elemental Analysis

X-ray photoelectron spectroscopy (XPS) analysis was performed using the measurement device and under the conditions as set forth below, and elemental analysis of silicon, nitrogen, and oxygen in a depth direction of the gas barrier layer laminate in the obtained gas barrier film was performed.

### X-Ray Photoelectron Spectroscopy (XPS) Analyzer

Product name: “Quantum2000” (available from ULVAC-PHI Inc.)
X-ray source: AlKα (1486.6 eV)
X-ray beam diameter: 100 μm

### Analysis Condition

Power value: 25 W
Applied voltage: 15 kV
Take-out angle: 45 degrees
Degree of vacuum: 5.0×10⁻⁸ Pa

### Analytical Element Peak

C: C1s
N: N1s
O: O1s
Si: Si2p

In addition, from the obtained element amounts, the film thickness at which the nitrogen element ratio was 5 atom % or more was calculated by the following calculation formula.

In the following calculation formula, N represents the amount of nitrogen element, Si represents the amount of silicon element, and O represents the amount of oxygen element.

Nitrogen element ratio (atom %)=[N/(N+Si+O)]×100

In the gas barrier layer laminate, the thicknesses of regions in which the nitrogen element ratio is 5 atom % or more are listed as modified film thicknesses in Table 1 below.

In Examples 1 and 2, based on the analysis by the XPS measurement, a horizontal axis is the thickness of the gas barrier layer laminate, the value of the nitrogen element ratio was plotted on a vertical axis, and a graph drawn based on plotted points was created. The created graphs are shown in FIGS. 4 and 5.

In addition, based on the analysis by XPS measurement, elemental analysis of silicon, nitrogen, and oxygen was performed from the surface layer of the gas barrier layer laminate up to 4 minutes at intervals of a sputtering time of 0.1 minutes.

Then, based on the results of the cross-sectional TEM observation and the results of the XPS measurement analysis performed on a reference sample shown below, it had been confirmed to take 1 minute to analyze the elements in a region up to 25 nm in the depth direction by the XPS measurement, and thus the value on the horizontal axis was converted to the thickness, with 1 plot being 2.5 nm.

### Preparation of and Measurement Method for Reference Sample Used in Conversion Between Measurement Time (Sputtering Time) and Thickness in the XPS Measurement Preparation of Reference Sample

On an untreated surface (PET face) of a polyethylene terephthalate (PET) film (“A-4160”, available from TOYOBO Co., Ltd.) that had undergone a primer treatment on one face and that had a thickness of 50 μm, perhydropolysilazane (available from DNF; weight average molecular weight: 10000 g/mol) was applied and heated and dried at 100° C. for 2 minutes, and thus a polysilazane layer having a film thickness of 200 nm was formed.

Next, plasma ion implantation was performed from the exposed surface side of the polysilazane layer using the plasma ion implantation device shown in the section “Example 1” under the same conditions as the conditions of Example 2 (the treatment time of the modification treatment was 800 seconds), the polysilazane layer was subjected to a modification treatment, a gas barrier layer was formed, and thus a reference sample was prepared.

Conversion from Sputtering Time to Thickness of Gas Barrier Layer

For the gas barrier layer of the reference sample, using a high-resolution electron microscope (TITAN 80-300, available from FEI), cross-sectional TEM observation was performed under a condition of an acceleration voltage of 200 kV, and based on the obtained HAADF-STEM image, the thickness de of the entire gas barrier layer and the nitrogen element ratio were determined.

For the same sample, the nitrogen element ratio (atom %) in the depth direction from the surface of the gas barrier layer was measured using the XPS measurement device and under the conditions as described above.

Then, from the measurement result of the cross-sectional TEM and the result of the XPS measurement, the correspondence between the sputtering time and the depth (thickness) of the gas barrier layer in the XPS measurement was confirmed, and the sputtering time was converted into the depth (thickness) of the gas barrier layer.

### Measurement of Water Vapor Transmission Rate

The gas barrier film prepared in each of the Examples and the Comparative Examples was cut into a round test piece with an area of 50 cm², and the water vapor transmission rate (WVTR) was measured under conditions: a temperature of 40° C., a relative humidity of 90% R. H., and a gas flow rate of 20 sccm using a water vapor transmission rate measuring device (device name “AQUATRAN (trade name) 2”, available from MOCON, Inc). The results are listed in Table 1 below.

### Evaluation of Bending Durability

In a non-tension U-shape folding tester (“DLDMLH-FS” available from Yuasa System Co., Ltd.), bending was performed 100000 times at bending radii of 3, 4, and 5 mm, with the gas barrier layer side being the outer side.

The water vapor transmission rates before and after the bending test were measured by the method described above.

The change rate between the water vapor transmission rates before and after the bending test was calculated from the following equation.

Change rate [%]=(water vapor transmission rate after bending test/water vapor transmission rate before bending test)×100

A smaller bending radius indicates stricter conditions.

The results are listed in Table 1 below.

TABLE 1

| | | | Thickness of | | | | Bending durability evaluation | | | | | | |
|---|---|---|---|---|---|---|---|---|---|---|---|---|---|
| | | | polysilazane- | | | | | Bending radius: | | Bending radius: | | Bending radius: | |
| | Modification | | based | | Modified film | | | 5 mm | | 4 mm | | 3 mm | |
| | treatment | | compound | | thickness | | Before | Number of | | Number of | | Number of | |
| | condition | | layer [nm] | | [nm] | | bending | times of bending: | | times of bending: | | times of bending: | |
| | | Treat- | First | Second | First | Second | test | 100000 times | | 100000 times | | 100000 times | |
| | | ment | layer | layer | layer | layer (in | WVTR | WVTR | Change | WVTR | Change | WVTR | Change |
| | Ionic | time | (layer | (layer | (in layer | layer | [g · m⁻² · | [g · m⁻² · | rate | [g · m⁻² · | rate | [g · m⁻² · | rate |
| | species | [sec] | (Y)) | (X)) | (YG)) | (XG)) | day⁻¹] | day⁻¹] | [%] | day⁻¹] | [%] | day⁻¹] | [%] |
| Example 1 | He | 600 | 250 | 20 | 44 | | 3.5 × 10⁻⁴ | 3.5 × 10⁻⁴ | 100 | 3.5 × 10⁻⁴ | 100 | 3.5 × 10⁻⁴ | 100 |
| Example 2 | He | 800 | 250 | 20 | 62 | | 1.0 × 10⁻⁴ | 1.0 × 10⁻⁴ | 100 | 1.0 × 10⁻⁴ | 100 | 1.0 × 10⁻⁴ | 100 |
| Com- | Ar | 200 | 200 | 250 | 15 | 15 | 4.9 × 10⁻⁴ | 4.9 × 10⁻⁴ | 100 | 9.3 × 10⁻² | 18980 | 5.5 × 10⁻¹ | 112245 |
| parative | | | | | | | | | | | | | |
| Example 1 | | | | | | | | | | | | | |

As listed in Table 1, it was confirmed that the gas barrier films of Examples 1 and 2 had a low water vapor transmission rate and excellent gas barrier properties in a state before the bending test. Further, in the evaluation of bending durability, when bending was performed under any conditions, the values of the water vapor transmission rate hardly changed before and after the test, and the gas barrier films were confirmed to be excellent in bending durability.

The gas barrier layer laminate included in each of the gas barrier films of Examples 1 and 2 was analyzed in a thickness direction from a surface opposite to the substrate included in the gas barrier film, using X-ray photoelectron spectroscopy (XPS); a thickness of the gas barrier layer laminate is plotted on a horizontal axis; a value of a nitrogen element ratio (atom %), which is a content of nitrogen relative to a total content of silicon, oxygen, and nitrogen elements, obtained by analysis results of the XPS is plotted on a vertical axis; and a graph is drawn based on plotted points, which is shown in each of FIGS. 4 and 5. The graphs shown in FIGS. 4 and 5 are graphs obtained by plotting the above-described data using a graph creation function (scatter diagram, smooth line) of the spreadsheet software “Microsoft (trade name) Excel (trade name)” available from Microsoft Corporation.

As shown in FIG. 4, it was confirmed that the graph according to Example 1 has one peak top P and has a shoulder S on the rising side of the peak top P.

Similarly, it was confirmed that, as shown in FIG. 5, the graph according to Example 2 has one peak top P and has a shoulder S on the rising side of the peak top P.

On the other hand, in the gas barrier film of Comparative Example 1, the values of the water vapor transmission rate after the bending test in the cases where the bending radii were 4 mm and 3 mm were significantly increased, and a decrease in gas barrier properties was confirmed. That is, it was confirmed that the gas barrier film was inferior in bending durability.

In Comparative Example 1, the first layer is formed, the modification treatment is performed, and then the second layer is formed. That is, the formation of the first layer and the second layer and the modification treatment are sequentially performed. It was confirmed that, as a result, sufficient bending durability was not obtained.

### REFERENCE SIGNS LIST

1: Substrate
2: Laminate in which polysilazane-based compound layer (X) and polysilazane-based compound layer (Y) are directly laminated
3: Gas barrier layer laminate in which gas barrier layer (XG) and gas barrier layer (YG) formed by simultaneous modification treatment are directly laminated
4: Gas barrier layer laminate in which gas barrier layer (XG) and gas barrier layer (YG) formed by sequential modification treatment are directly laminated
10: Laminate before modification treatment
20: Gas barrier film of embodiment according to Example
30: Gas barrier film of embodiment according to Comparative Example
X: Polysilazane-based compound layer (X)
Y: Polysilazane-based compound layer (Y)
XG: Gas barrier layer (XG)
X1: Modified region
X2: Unmodified region
YG: Gas barrier layer (YG)
Y1: Modified region
Y2: Unmodified region
P: Peak top
S: Shoulder

1. A method for manufacturing a gas barrier film, the method comprising at least the following steps 1 to 3 in this order:
step 1: forming an unmodified polysilazane-based compound layer (Y);
step 2: forming an unmodified polysilazane-based compound layer (X) on an exposed surface of the layer (Y) to directly laminate the layer (Y) and the layer (X); and
step 3: forming a gas barrier layer laminate in which a gas barrier layer (XG) and a gas barrier layer (YG) are directly laminated by performing a modification treatment from a surface of the layer (X) on a side opposite to the layer (Y) to simultaneously perform the modification treatment on at least a part of the layer (X) and the layer (Y).

2. The method for manufacturing a gas barrier film according to claim 1, wherein the step 1 is the following step 11:
step 11: forming the unmodified polysilazane-based compound layer (Y) on at least one surface side of a substrate.

3. The method for manufacturing a gas barrier film according to claim 1, wherein, in the step 3, the modification treatment is performed on the entire layer (X) as well as on at least a part of the layer (Y) in a thickness direction of the layer (Y) from an interface between the layer (X) and the layer (Y) toward a surface of the layer (Y) opposite to the layer (X).

4. The method for manufacturing a gas barrier film according to claim 1, wherein a ratio [(Yt)/(Xt)] of a thickness (Yt) of the layer (Y) to a thickness (Xt) of the layer (X) is 1 or more.

5. The method for manufacturing a gas barrier film according to claim 1, wherein the gas barrier layer laminate has a thickness of from 25 to 10000 nm.

6. A gas barrier film comprising: a substrate; and a polysilazane-based compound-derived layer on at least one surface side of the substrate, wherein the polysilazane-based compound-derived layer, when analyzed in a thickness direction from a surface thereof opposite to the substrate using X-ray photoelectron spectroscopy (XPS), shows a graph having a peak having at least one shoulder at a location different from a peak top, where a horizontal axis is a thickness of the polysilazane-based compound-derived layer, a value of a nitrogen element ratio (atom %), which is a content of nitrogen relative to a total content of silicon, oxygen, and nitrogen elements, obtained by analysis results of the XPS, is plotted on a vertical axis, and the graph is drawn based on plotted points.

7. The gas barrier film according to claim 6, wherein the shoulder is an inflection point.

8. The gas barrier film according to claim 6, wherein the shoulder is present within a range of ±50 nm from a position of the peak top.

9. The gas barrier film according to claim 6, wherein the shoulder is present on a rising side of the peak top.

10. The gas barrier film according to claim 6, wherein, in the polysilazane-based compound-derived layer, a region in which the nitrogen element ratio is 5 atom % or more has a thickness of from 5 to 10000 nm.

11. A gas barrier film comprising: a substrate; and a gas barrier layer laminate provided on at least one surface side of the substrate and comprising a gas barrier layer (XG) not adjacent to the substrate and a gas barrier layer (YG) located closer to the substrate than the layer (XG) and adjacent to the layer (XG), the gas barrier layers (XG) and (YG) being directly laminated,
wherein the gas barrier layer laminate, when analyzed in a thickness direction from a surface thereof opposite to the substrate using X-ray photoelectron spectroscopy (XPS), shows a graph having a peak having at least one shoulder at a location different from a peak top, where a horizontal axis is a thickness of the gas barrier layer laminate, a value of a nitrogen element ratio (atom %), which is a content of nitrogen relative to a total content of silicon, oxygen, and nitrogen elements, obtained by analysis results of the XPS, is plotted on a vertical axis, and the graph is drawn based on plotted points.
